(19) United States
(12) Patent Application Publication
(10) Pub. No.: US 2008/0070011 A1
(43) Pub. Date: Mar. 20, 2008

(54) Method for manufacturing multi-layer printed circuit board

(75) Inventors: Sung-Il Oh, Seoul (KR); Jae-Woo Joung, Suwon-si (KR); Sung-Nam Cho, Suwon-si (KR)

Correspondence Address: MCDERMOTT WILL & EMERY LLP, 600 13TH STREET, N.W., WASHINGTON, DC, 20005-3096, US

(73) Assignee: SAMSUNG ELECTRO-MECHANICS CO., LTD.

(21) Appl. No.: 11/902,237

(22) Filed: Sep. 20, 2007

(30) Foreign Application Priority Data
Sep. 20, 2006 (KR) 10-2006-0091293

(51) Int. Cl. C23C 14/04; B05D 3/06; B32B 3/10

(52) U.S. Cl. 428/208; 118/50; 427/555

(57) ABSTRACT

The present invention relate to a method for manufacturing a multi-layer printed circuit board using inkjet printing and a vacuum printing equipment, in particular, a method for manufacturing a multi-layer printed circuit board including; preparing a board; forming wiring using inkjet printing on the board; forming an insulation layer using a thermosetting polymer compound on the board; forming via holes by a laser irradiation on the insulation layer; and filling metal nanoparticle paste in the via holes by a vacuum printing method.

### CROSS-REFERENCE TO RELATED APPLICATIONS

This application claims the benefit of Korean Patent Application No. 10-2006-0091293 filed on Sep. 20, 2006, with the Korea Intellectual Property Office, the contents of which are incorporated here by reference in their entirety.

### BACKGROUND

1. Technical Field

The present invention relates to a method for manufacturing a multi-layer printed circuit board, a vacuum printing equipment used therein, and a multi-layer printed circuit board manufactured thereby

2. Description of the Related Art

With the advent of the ubiquitous age, studies about methods of manufacturing low cost electronic components are currently under way. Up to now, for forming conductive wiring of electronic components, a photolithography method which is composed with complicated processes of plating mask, exposure, developing, etching, peeling, washing, dry, has been widely used.

Although the photolithography method is a suitable for mass production by forming conductive wirings via a wet process including plating mask, photosensitive material application (or lamination), selective exposure, chemical etching and the like, there are following problems with small quantity batch production.

First, the mask plating process, which uses a mask for selective exposure of a photosensitive layer applied or laminated on a copper foiled board of a multi-layer printed circuit board, forms patterns by using a high effective laser plotter on a PET film. As such a mask plating process affects directly to the quality of the conductive wiring formed on the multi-layer printed circuit board, pin holes, opens and short phenomenon of the printed and formed pattern on the PET film can cause the formation of defective conductive wirings. Therefore, after the mask plating process, a inferior wiring detection process is essential. Also because the PEP film for the mask plating can be easily contracted and expanded during printing process and/or developing process and by temperature changes, a X, and Y scale examination process for measuring degree of contraction and expansion is required and further, if degree of either contraction or expansion is severe, the plating process has to be repeated.

Second, the photolithography process, which is a wet process and accomplished after the mask plating process, requires high manufacturing cost for large-scale facilities and equipments for application or lamination process of photosensitive material, curing process(exposure) of the photosensitive layer by ultraviolet irradiation, elimination process(development) of the non-hardened photosensitive layer, etching process of copper foils and removing process(exfoliation) of the remained photosensitive layer for forming desirable conductive wirings on the printed circuit board and causes many environmental problems due to use of large volume of organic solvents and production of large volume of waste organic solvents. Further, such a wet process can cause deformation due to contraction and expansion of substrates and/or printed circuit boards and thus deteriorate interlayer alignments.

Last, in case of connecting interlayers through the wet process like photolithography process, there are still problems of increased defect rate due to deformation of boards with contraction and expansion and environmental problems as described above. To solve these problems, a dry process is recently introduced in which photo-vias are formed though exposure and developing process after applying or laminating a photosensitive resin and a conductive paste is printed through a screen printing. However, this process also performs the mask plating process for forming photo-vias, the exposure process of a photosensitive layer and the developing process. Therefore, there are still mask plating problems and difficulties to apply for small quantity batch production.

### SUMMARY

As this invention is on behalf of settle the above-mentioned technical problems, the invention provides a method for manufacturing a multi-layer circuit board which does not require a wet process and allows interlayer connections without forming a mask.

The invention further provides a multi-layer circuit board manufactured thereby.

The invention further provides a vacuum printing equipment which is usable for interlayer connections on the multi-layer circuit board.

An aspect of the invention, on behalf of settle the above-mentioned technical problems, provides a method for manufacturing a multi-layer printed circuit board including; preparing a board; forming wiring on the board by using an inkjet printing; forming an insulation layer on the board by using a thermosetting polymer compound; forming via holes on the insulation layer by a laser irradiation; and filling metal nanoparticle paste in the via holes by a vacuum printing method.

According to one embodiment of the invention, in the step of forming wiring, the wiring is formed by printing a metal nanoparticle ink on the board by the inkjet printing and curing at about 150-300° C.

Here, the metal nanoparticle ink includes one or more metal nanoparticles selected from the group consisting of gold, silver, palladium, platinum, copper, nickel, cobalt, tungsten, iron and mixtures thereof. Also, the size of the metal nanoparticles is about 1-100 nm.

In the step of forming an insulation layer, the thermosetting polymer compound may involve an epoxy resin.

According to one embodiment of the invention, the step of forming the insulation layer may include; forming the insulation layer of the thermosetting polymer compound in a dry film type; stacking the dry film typed insulation layers on the board by a lamination process; and heat-curing the insulation layer at about 100-250° C. for 120 minutes.

The laser used for forming via holes may be CO₂ laser or YAG laser.

A method for manufacturing a multi-layer circuit board according to the invention may further comprise desmear treating on the surface of the insulation layer after forming via holes.

According to one embodiment, the filling metal nanoparticle paste in the via holes uses a vacuum printing equipment which includes a vacuum chamber, a vacuum pump connected to the vacuum chamber; a head which is placed inside the vacuum chamber and able to screen-print the metal nanoparticle paste; a squeeze placed inside the head; and a connecting part which is connected to the head and maintains the pressure inside the head to be higher than that inside the vacuum chamber by being connected to air outside the vacuum chamber.

Here, the nanoparticle paste is filled into the via holes by the pressure difference between inside the vacuum chamber and inside the head and the internal pressure of the squeeze.

Furthermore, a method for manufacturing a multi-layer circuit board according to the invention may further comprise heat treatment of the filled metal nanoparticle paste at about 150-300° C. for about 30-120 minutes after the step of forming the insulation layer.

In the invention, the multi-layer circuit board can be manufactured by repeating from the step of preparing a board to the step of filling metal nanoparticle paste.

Another aspect of this invention provides a multi-layer printed circuit board manufactured by the method described above.

Another aspect of this invention provides a vacuum printing equipment, being used to fill the metal nanopartile paste into the via holes for connecting between layers, including; a vacuum chamber; a vacuum pump connected to the vacuum chamber; a head which is placed inside the vacuum chamber and screen-prints metal nanoparticle paste; a squeeze placed inside the head; and a connecting part which is connected to the head and maintains the pressure inside the head to be higher than that inside the vacuum chamber by being connected to air outside the vacuum chamber.

### BRIEF DESCRIPTION OF THE DRAWINGS

FIG. 1 is a flowchart schematically illustrating a method for manufacturing a multi-layer printed circuit board according to the present invention.

FIG. 2 is a drawing representing the vacuum printing equipment used for interlayer connection of the multi-layer printed circuit board of the present invention.

### DETAILED DESCRIPTION

Hereinafter, referring to the appended drawings, a method for manufacturing a multi-layer printed circuit board and a vacuum printing equipment used in the same according to the present invention will be described in detail.

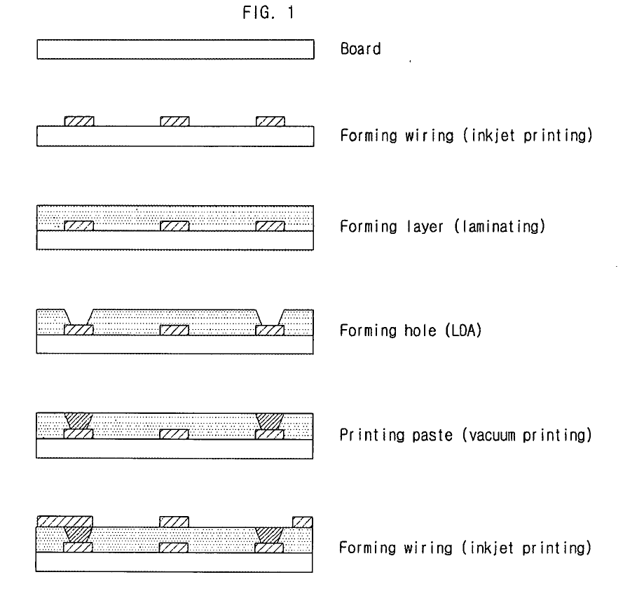

FIG. 1 is a flowchart schematically illustrating a method for manufacturing a multi-layer printed circuit board according to the present invention.

Referring to FIG. 1, a method for manufacturing a multi-layer printed circuit board according to the invention involves preparing a board; forming wiring using an inkjet printing on the board; forming an insulation layer using a thermosetting polymer compound on the board; forming via holes by laser irradiation on the insulation layer; and filling metal nanoparticle paste in the via holes by a vacuum printing method.

A method for manufacturing a multi-layer printed circuit board according to the invention, firstly, prepares the board (the step of forming wiring).

Here, any polymer board may be uses as the board without limitation if it has thermosetting and insulating properties and is commonly used for a printed circuit board (PCB). Examples of the board include a phenol or epoxy resin board and a polyimide board appropriate to a flexible circuit board.

After the board is prepared, wiring can be formed using an inkjet printing on the board (the step of forming wiring)

The inkjet printing is a technology to form desired patterns by the direct printing according to pre-designed data, and thus, eliminates mask plating, laminatng, exposure, developing, etching, peeling processes, which are required of the conventional photolithography process. Accordingly, the inkjet printing method may not only reduce manufacturing cost but also increase the quality of printed wirings by eliminating such unnecessary processes.

According to one embodiment of the invention, in the step of forming wiring, the wiring is formed by printing a metal nanoparticle ink on the board by the inkjet printing method and curing at about 150-300° C. Here, the metal nanoparticle ink includes one or more metal nanoparticles selected from the group consisting of gold, silver, palladium, platinum, copper, nickel, cobalt, tungsten, iron and mixtures thereof. Also, the size of the metal nanoparticles may be about 1-100 nm.

Generally, when the size of the metal nanoparticles is 100 nm or less, a relative surface area of particles tremendously increases and the particles show different properties from general metal particles. Especially a boiling point of the metal particles becomes lowered so that the particles start melting at about 200° C., curing is possible and it allows forming wiring on the board which is weak in heat since electric conductivity of the cured metal pattern is similar in value to that of bulk metal. If the size of the metal nanoparticles is less than 1 nm, it may be difficult to control nanoparticle characteristics and practically it is difficult to have the size of less than 1 nm.

If the metal nanoparticles having the particle size as mentioned above are used, the printed wiring can be cured at about 150-300° C., more preferably at about 200-250° C. If the temperature is lower than 150□, it has a difficulty to effectively melt the metal nanoparticles and if the temperature is higher than 300□, it causes degeneration or decomposition of the polymer board.

After forming wiring like this, the insulation layer is formed by using a thermosetting polymer compound on the board (the step of forming an insulation layer).

The thermosetting polymer compound is used as a material for forming an interlayer insulation layer of the multi-layer printed circuit board. In case of using a thermoplastic polymer compound, it has poor heat resistance and thus, may deteriorate the interlayer alignment due to contraction or decomposition during the curing process of the conductive wiring printed with the metal nanoparticle ink. In case of using photo-cured polymer compound, although it has a superior heat-resistance, it has a hygroscopic property which deteriorates mechanical properties and practically limit the type of usable materials.

An example of the thermosetting polymer compound used for the insulation layer includes an epoxy resin but it is not limited to this.

According to an embodiment, the step for forming an insulation layer may include forming the insulation layer of the thermosetting polymer compound in a dry film type; stacking the dry film typed insulation layer on the board by a lamination process; and heat-curing the insulation layer at about 100-250° C. for 120 minutes.

After forming the dry film, hot-pressed lamination at 100-200° C. provides a superior smoothness if the insulation layer is formed through the lamination process, (thickness variation of the insulation layer is within ±5%), and it also allows forming fine wirings by the inkjet printing and further manufacturing high density wiring boards. The insulation layer is formed by curing the laminated insulation layer of the polymer compound for 120 minutes at 100 to 250° C.

After forming the insulation layer, via holes are formed by a laser irradiation on the insulation layer (the step of forming via holes).

In prior art, via holes are formed by forming an insulation layer composed of a photosensitive resin, mask plating, exposure and developing process, but because UV light used for the exposure process is a diffusion light, via holes formed after developing are not clear and the size of via holes to be implemented is limited.

On the contrary, via holes for the interlayer connection are formed by the LDA (Laser Direct Ablation), namely elimination of appropriate parts of the insulation layer by a laser irradiation. As laser is a high-integratable light, resolution of the via holes to be implemented is superior and additional processes such as mask plating are unnecessary because of using a direct pattern forming method. In this invention, superior resolution can be acquired by using a laser which may be CO₂ laser or YAG laser, 0.5 mm size of via holes can be formed.

The method for manufacturing a multi-layer printed circuit board according to the invention may further include desmear treating on the surface of the insulation layer after forming via holes. If the surface of the insulation layer, where the via holes are formed, is desmear-treated with an etching solution such as potassium permanganate, roughness is formed on the surface of the insulation layer, which allows better adhesion of metal nanoparticle paste or metal nanoink when via holes are formed or inkjet wiring is formed on following process.

After via holes are formed on the insulation layer, the metal nanoparticle paste is filled into the via holes by a vacuum printing method (the step of filling metal nanoparticle paste).

In prior art, for filling via holes with conductive materials, plating or pushing conductive paste with a squeeze has been used. However, in case of employing the plating process, expansion of the board may be occurred because it is a wet process. Also, In case of employing the method of pushing conductive paste with a squeeze, it may be difficult to have a high conductivity due to a residual binder in the conductive paste, it may cause degeneration or decomposition of the polymer compound of the board when heated at 500° C. or higher to eliminate a residual binder, and it may deteriorate durability due to crack, air gap and so on which is resulted from not filling the via holes with the paste densely enough.

Therefore, in this invention, the interlayer connection is provided by filling the metal nanoparticle paste into the via holes by the vacuum printing method. The metal nanoparticle paste used in this process becomes paste through condensing a metal nanoink which is used for forming the inkjet wiring and is used by transformed to be suitable for the vacuum printing.

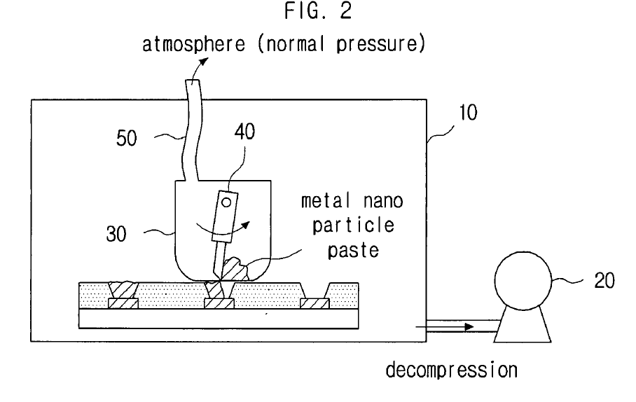

The method of filling the nanoparticle paste into the via holes can be achieved by employing a vacuum printing equipment illustrated in FIG. 2.

Referring to FIG. 2, the vacuum printing equipment includes a vacuum chamber 10; a vacuum pump 20pump connected to the vacuum chamber 10; a head 30 which is placed inside the vacuum chamber and screen-prints metal nanoparticle paste; a squeeze 40 placed inside the head 30; and a connecting part 50 which is connected to the head 30 and maintains the pressure inside the head 30 to be higher than that inside the vacuum chamber 10 by being connected to air outside the vacuum chamber 10.

A board, on which the printing is to be performed, is placed in the vacuum chamber 10 connected to the vacuum pump 20, the squeeze 40 is equipped inside the head 30, the head 30 is connected to the exterior air by the connecting part 50 so that the pressure inside the head 30 is maintained higher than that inside the vacuum chamber 10.

If the metal nanoparticle paste is packed in the head 30 and the squeeze 40 is operated while the inside of the vacuum chamber 10 is decompressed by the vacuum pump 20, the metal nanoparticle paste is filled into the via holes by the pressure difference between inside the vacuum chamber 10 and inside the head 30 and the internal pressure of the squeeze 40. If such a vacuum printing method is used, the metal nanoparticle paste may be filled densely into the via holes, a solvent in the paste is eliminated easily so that the printed circuit board with high reliability can be manufactured because the formation of crack or air gap is prevented during the curing process.

After the metal nanoparticle paste is filled into the via holes, the filled metal nanoparticle paste is cured by heat treatment at about 150-300° C. for about 30-120 minutes.

According to the invention, a reliable multi-printed circuit board can be manufactured by performing from preparing a board to filling metal nanoparticle paste repeatedly with other additional steps, if needed.

Hereinafter, while the spirit of the invention has been described in detail with reference to particular embodiments, the following embodiments are for illustrative purposes only and do not limit the invention.

Preparation Example 1: Preparation of Silver Nanoparticle Paste

1,200 g Of polyvinyl pyrrolidone, 56.2 g of glucose and 2,600 g of ethylene glycol were placed in a 5L 3-necked flask and heated to 150° C. while stirring. When the reaction mixture was completely dissolved, 600 g of AgNO₃ completely dissolved in 800 g of ethylene glycol was poured into the reaction flask quickly. At this time, the reaction mixture was black and turned to brown and then to bilious color with time. When the reaction temperature reached to 160° C., excessive ethylene glycol was added to terminate the reaction for prevent from further particle growth. After excessive acetone was added and mixed with the terminated reaction mixture, silver nanoparticles were obtained by precipitation with centrifugation at 2500 rpm for 2 minutes and drying. The following method was used to prepare silver nanoparticle paste suitable for the vacuum printing. The silver nanoparticles were dispersed into ethanol to be 80 wt % of silver solution and then ultrasonic-dispersed by using ultrasonic waves. To eliminate the particles which had weak dispersity or were conglomerated, high speed centrifugation and filtering were performed. Centrifugation was performed at 3000 pm for 10 minutes and then only supernatant was collected and filtered through a 1 μm caliber filter to obtain silver colloid. Silver nanoparticle paste for the vacuum printing was manufactured by mixing 75 g of silver colloid, 10 g of ethylene glycol, 10 g of glycerol and 5 g of polyethylene glycol.

### EXAMPLE

After silver nanoink was printed on a polyimide film as a board by using an inkjet printer for nanometal ink printing, it was cured at 200° C. for 1 hour to form wiring. For forming an insulation layer, ABF-SH film (sold by Ajinomoto fine tech., Japan), which is coated with an epoxy compound on a PET film, was vacuum laminated on both sides of the board at 90° C., 2.0 mbar for 50 seconds by using the Morton CVA 725 vacuum laminator and then the PET film was removed after hot-pressing at 100° C., 2 kgf/cm², for 2 minutes. After hardening at 170° C. for 30 minutes, via holes were formed by using a CO₂ laser and then desmear-treated on the surface of the insulation layer with potassium permanganate to provide roughness. The sliver nanoparticle paste which was prepared in Preparation Example 1 was filled into the via holes using the vacuum printing equipment illustrated in FIG. 2, and the result was cured at 200° C. for 60 minutes to provide the board. A multi-layer printed circuit board was manufactured by repeating the processes illustrated above.

This invention is not limited in described embodiments, many transformations can be appreciated by those skilled in the art.

According to a method for manufacturing a multi-layer printed circuit board of the invention above-mentioned, it may reduce manufacturing cost because of the direct printing method which eliminates the photolithography process when wiring is formed, be environmental-friendly, remove inferiority factors associated with the board expansion, provide superior smoothness because of formation of the insulation layer by the laminating method, provide high resolution of the via holes and no cracks and air gaps because of interlayer connection by LDA and vacuum printing. Also, the method allows curing at a low temperature and providing high conductivity using the metal nanoparticle paste.

What is claimed is:

1. A method of manufacturing a multi-layer printed circuit board comprising:
preparing a board;
forming wiring using an inkjet printing on the board;
forming an insulation layer using a thermosetting polymer compound on the board;
forming via holes by a laser irradiation on the insulation layer; and
filling metal nanoparticle paste in the via holes by a vacuum printing method.

2. The method of claim 1, wherein in the step of forming wiring, the wiring is formed by printing a metal nanoink by an inkjet printing on the board and curing at about 150-300□.

3. The method of claim 1, wherein the metal nanoink comprises one or more metal nanoparticles selected from the group consisting of gold, silver, palladium, platinum, copper, nickel, cobalt, tungsten, iron and mixtures thereof.

4. The method of claim 3, wherein size of the metal nanoparticles is about 1-100 nm.

5. The method of claim 1, wherein the thermosetting polymer compound comprises an epoxy resin.

6. The method of claim 1, wherein in the step of forming an insulation layer comprises;
forming the insulation layer of the thermosetting polymer compound in a dry film type;
stacking the dry film typed insulation layer on the board by a lamination process; and
heat-curing the insulation layer at about 100-250° C. for 120 minutes.

7. The method of claim 1, wherein the laser is CO₂ laser or YAG laser.

8. The method of claim 1, further comprising desmear-treating the surface of the insulation layer after the forming the via holes.

9. The method of claim 1, wherein the filling metal nanoparticle paste uses a vacuum printing equipment which comprises a vacuum chamber, a vacuum pump connected to the vacuum chamber; a head which is placed inside the vacuum chamber and able to screen-print the metal nanoparticle paste; a squeeze placed inside the head; and a connecting part which is connected to the head and maintains the pressure inside the head to be higher than that inside the vacuum chamber by being connected to air outside the vacuum chamber.

10. The method of claim 1, wherein the filling metal nanoparticle paste by the vacuum printing method is performed by filling metal nanoparticle paste into the via holes by the pressure difference between inside the vacuum chamber and inside the head, and the internal pressure of the squeeze.

11. The method of claim 1, further comprising heating treatment the filled metal nanoparticle paste at about 150-300° C. for about 30-120 minutes after filling the metal nanoparticle paste.

12. The method of claim 1, wherein from the step of preparing a board to the step of filling metal nanoparticle paste is repeated.

13. A multi-layer printed circuit board manufactured by the method of claim 1.

14. A vacuum printing equipment, used to fill metal nanoparticle paste into via holes for connection between layers, comprising;
a vacuum chamber;
a vacuum pump connected to the vacuum chamber;
a head which is placed in the vacuum chamber and screen-prints metal nanoparticle paste;
a squeeze placed inside the head; and
a connecting part which is connected to the head and maintains the pressure inside the head to be higher than that inside the vacuum chamber by being connected to air outside the vacuum chamber.
